(19) United States
(12) Patent Application Publication
(10) Pub. No.: US 2023/0370048 A1
(43) Pub. Date: Nov. 16, 2023

(54) BULK-ACOUSTIC WAVE RESONATOR

(71) Applicant: SAMSUNG ELECTRO-MECHANICS CO., LTD., Suwon-si (KR)

(72) Inventors: Kwang Su KIM, Suwon-si (KR); Jae Hyoung GIL, Suwon-si (KR); Moon Chul LEE, Suwon-si (KR); Yong Suk KIM, Suwon-si (KR); Dong Hyun PARK, Suwon-si (KR); Tae Kyung LEE, Suwon-si (KR)

(73) Assignee: SAMSUNG ELECTRO-MECHANICS CO., LTD., Suwon-si (KR)

(21) Appl. No.: 18/101,267

(22) Filed: Jan. 25, 2023

(30) Foreign Application Priority Data
May 11, 2022 (KR) 10-2022-0057960

(51) Int. Cl. H03H 9/17; H03H 9/13; H03H 9/02

(52) U.S. Cl. CPC H03H 9/174; H03H 9/131; H03H 9/02015; H03H 9/173

(57) ABSTRACT

A bulk-acoustic wave resonator includes a substrate; a lower electrode, disposed on the substrate, comprising a first inclined surface and a second inclined surface; and an insertion layer disposed on an edge of the lower electrode. The first inclined surface extends from an inclined surface of the insertion layer in a region disposed inside the insertion layer. The second inclined surface extends from the first inclined surface in a region inside a region of the first inclined surface.

### CROSS-REFERENCE TO RELATED APPLICATION(S)

This application claims the benefit of priority to Korean Patent Application No. 10-2022-0057960 filed on May 11, 2022, in the Korean Intellectual Property Office, the disclosure of which is incorporated herein by reference in its entirety.

### BACKGROUND

### 1. Field

The following description relates to a bulk-acoustic wave resonator.

### 2. Description of Related Art

Recently, the microelectromechanical system (MEMS) technology market has been expanding into an innovative system miniaturization field that will lead to various technological fields centered on mobile and IT-related fields in the future. To implement miniaturization, multifunctionalization, and high performance in the field of wireless communication systems, a device using a BAW filter device plays a very important role, as an essential component.

A BAW filter includes a combination of a series resonator and a shunt resonator, and has a structure in which the series resonator and the shunt resonator are connected to each other in a ladder manner. For filtering of a desired frequency band, a device is manufactured by selecting materials and thicknesses of a lower electrode, a piezoelectric material, an upper electrode, and a frequency adjustment layer, and arranging resonators. In the manufacturing process, a thickness variation may inevitably occur during the deposition of a material, and such a thickness variation may affect a variation of an initial frequency of a resonator.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a bulk-acoustic wave resonator includes a substrate; a lower electrode, disposed on the substrate, comprising a first inclined surface and a second inclined surface; and an insertion layer disposed on an edge of the lower electrode. The first inclined surface extends from an inclined surface of the insertion layer in a region disposed inside the insertion layer. The second inclined surface extends from the first inclined surface in a region inside a region of the first inclined surface.

An inclination angle of the first inclined surface and an inclination angle of the second inclined surface may be different from each other.

The inclination angle of the first inclined surface may be greater than the inclination angle of the second inclined surface.

A thickness of the lower electrode in a region disposed inside the second inclined surface may be thinner than the thickness of the lower electrode disposed in a region in which the first and second inclined surfaces are disposed.

A thickness difference at a same position of the lower electrode and another lower electrode of another bulk-acoustic wave resonator adjacently disposed may be 30 Å or less.

The lower electrode may be formed of gold (Au), molybdenum (Mo), iridium (Ir), aluminum (Al), platinum (Pt), titanium (Ti), tungsten (W), palladium (Pd), tantalum (Ta), chromium (Cr), nickel (Ni), or a metal alloy, including at least one of gold (Au), molybdenum (Mo), iridium (Ir), aluminum (Al), platinum (Pt), titanium (Ti), tungsten (W), palladium (Pd), tantalum (Ta), chromium (Cr), and nickel (Ni).

The bulk-acoustic wave resonator may further include a piezoelectric layer disposed to cover the insertion layer and the lower electrode, and an upper electrode disposed to cover at least a portion of the piezoelectric layer.

The bulk-acoustic wave resonator may further include a membrane layer disposed between the substrate and the lower electrode, the membrane layer having a cavity disposed therebelow; an etch stop layer disposed outside the cavity; and a sacrificial layer disposed outside the etch stop layer.

The bulk-acoustic wave resonator may further include a passivation layer disposed on an upper portion of the upper electrode, and a metal pad connected to the lower electrode and the upper electrode.

In another general aspect, a bulk-acoustic wave resonator includes a substrate; a lower electrode disposed on the substrate; an insertion layer disposed on an edge of the lower electrode; a piezoelectric layer disposed to cover the insertion layer and the lower electrode; and an upper electrode disposed to cover at least a portion of the piezoelectric layer. A portion of the lower electrode, disposed in an active region in which the lower electrode, the piezoelectric layer, and the upper electrode all overlap each other, includes a first inclined surface extending from an inclined surface of the insertion layer, and a second inclined surface extending from the first inclined surface.

An inclination angle of the first inclined surface and an inclination angle of the second inclined surface may be different from each other.

The inclination angle of the first inclined surface may be greater than the inclination angle of the second inclined surface.

A thickness of the lower electrode in a region disposed inside the second inclined surface may be thinner than the thickness of the lower electrode disposed in a region in which the first and second inclined surfaces are disposed.

A difference between a maximum thickness and a minimum thickness of the portion of the lower electrode in the active region may be 30 Å or less.

Other features and aspects will be apparent from the following detailed description, the drawings, and the claims.

### BRIEF DESCRIPTION OF DRAWINGS

FIG. 1 is a plan view illustrating a bulk-acoustic wave resonator according to an example embodiment of the present disclosure.

FIG. 2 is a cross-sectional view taken along line I-I′ of FIG. 1.

FIG. 3 is a cross-sectional view taken along line II-II′ of FIG. 1.

FIG. 4 is an enlarged view illustrating portion A of FIG. 2.

FIG. 5 is an enlarged view illustrating portion B of FIG. 2.

FIGS. 6 to 13 are explanatory diagrams illustrating a process of manufacturing a lower electrode.

FIG. 14 is a graph illustrating a difference between a maximum thickness and a minimum thickness of a lower electrode in an active region according to the related art, and a difference between a maximum thickness and a minimum thickness of a lower electrode in an active region according to the present disclosure.

Throughout the drawings and the detailed description, the same reference numerals refer to the same or like elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after understanding of the disclosure of this application may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms such as “above,” “upper,” “below,” and “lower” may be used herein for ease of description to describe one element's relationship to another element as shown in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes shown in the drawings may occur. Thus, the examples described herein are not limited to the specific shapes shown in the drawings, but include changes in shape that occur during manufacturing.

The features of the examples described herein may be combined in various ways as will be apparent after an understanding of the disclosure of this application. Further, although the examples described herein have a variety of configurations, other configurations are possible as will be apparent after an understanding of the disclosure of this application.

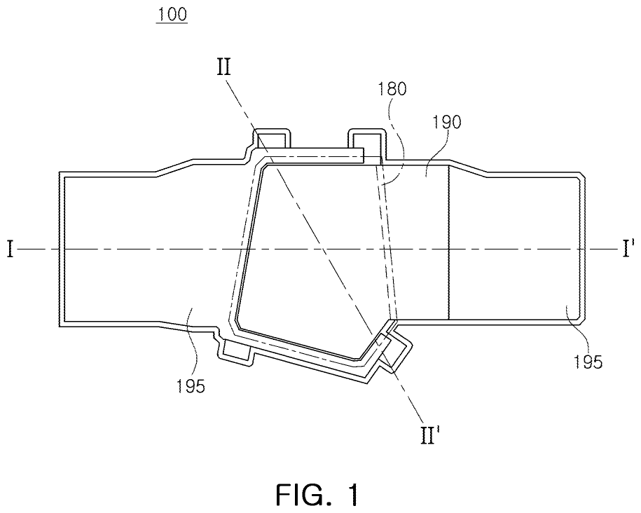

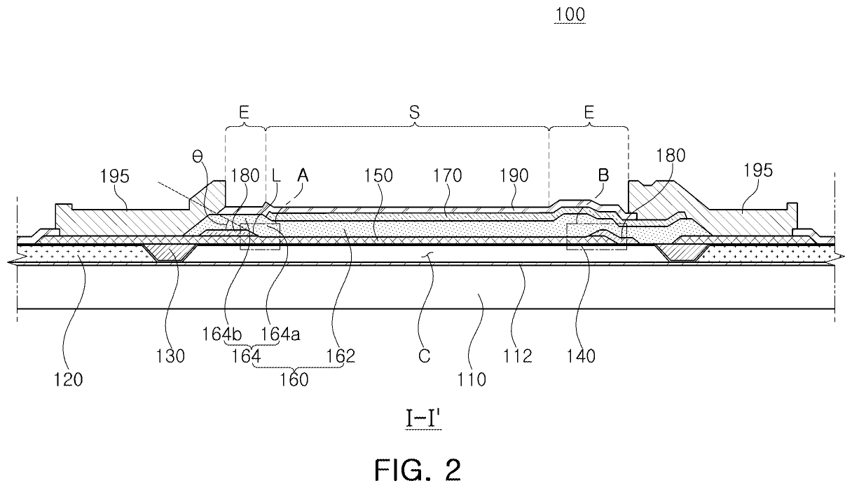

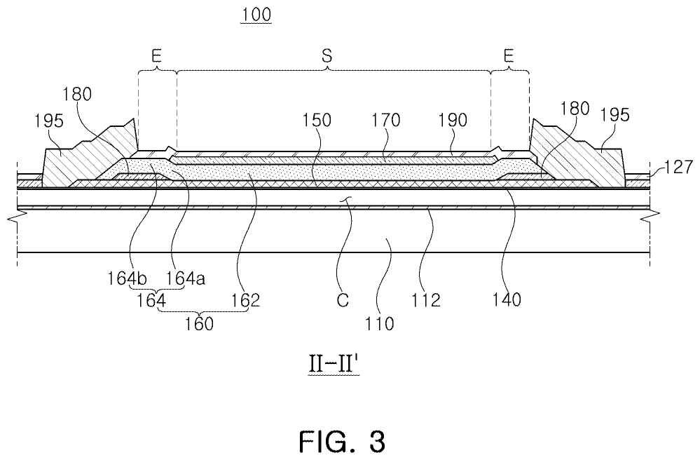

FIG. 1 is a plan view illustrating a bulk-acoustic wave resonator according to an example embodiment of the present disclosure. FIG. 2 is a cross-sectional view taken along line I-I′ of FIG. 1. FIG. 3 is a cross-sectional view taken along line II-II′ of FIG. 1.

Referring to FIGS. 1 to 3, a bulk-acoustic wave resonator 100 according to an example embodiment of the present disclosure may include, as an example, a substrate 110, a sacrificial layer 120, an etch stop portion 130, a lower electrode 150, a piezoelectric layer 160, an upper electrode 170, an insertion layer 180, a passivation layer 190, and a metal pad 195.

The substrate 110 may be a silicon substrate. For example, a silicon wafer or a silicon on insulator (SOI)-type substrate may be used as the substrate 110.

An insulating layer 112 may be formed on an upper surface of the substrate 110, and may electrically isolate the substrate 110 from a component disposed thereon. In addition, the insulating layer 112 may serve to prevent the substrate 110 from being etched by etching gas when a cavity C is formed in a manufacturing process.

In this case, the insulating layer 112 may be formed of any one or any combination of any two or more of silicon dioxide (SiO₂), silicon nitride (Si₃N₄), aluminum oxide (Al₂O₂), and aluminum nitride (AlN), and may be formed through one of chemical vapor deposition, RF magnetron sputtering, and evaporation.

The sacrificial layer 120 may be formed on the insulating layer 112, and the cavity C and the etch stop portion 130 may be disposed inside the sacrificial layer 120. The cavity C may be formed by removing a portion of the sacrificial layer 120 during manufacturing. As described above, as the cavity C is formed inside the sacrificial layer 120, the lower electrode 150 or the like disposed on an upper portion of sacrificial layer 120 may be formed to be flat.

The etch stop portion 130 may be disposed along a boundary of the cavity C. The etch stop portion 130 may serve to prevent a portion other than a cavity region from being etched in a process of forming the cavity C.

The membrane layer 140 may form the cavity C together with the substrate 110. As an example, the membrane layer 140 may serve to prevent the lower electrode 150 from being damaged by etching gas when the sacrificial layer is removed to form the cavity C.

The lower electrode 150 may be formed on the membrane layer 140, and a portion thereof may be disposed on an upper portion of the cavity C. In addition, the lower electrode 150 may be used as one of an input electrode and an output electrode for inputting and outputting an electrical signal such as a radio frequency (RF) signal or the like.

The lower electrode 150 may be formed using, as an example, a conductive material such as molybdenum (Mo) or alloys thereof. However, the present disclosure is not limited thereto, and the lower electrode 150 may be formed of a conductive material, such as ruthenium (Ru), tungsten (W), iridium (Ir), platinum (Pt), copper (Cu), titanium (Ti), tantalum (Ta), nickel (Ni), chromium (Cr), or the like, or alloys thereof.

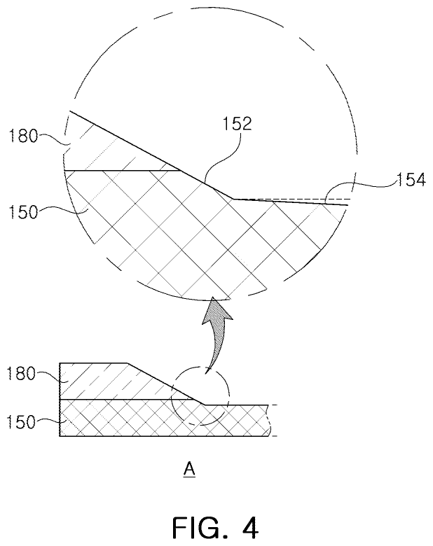

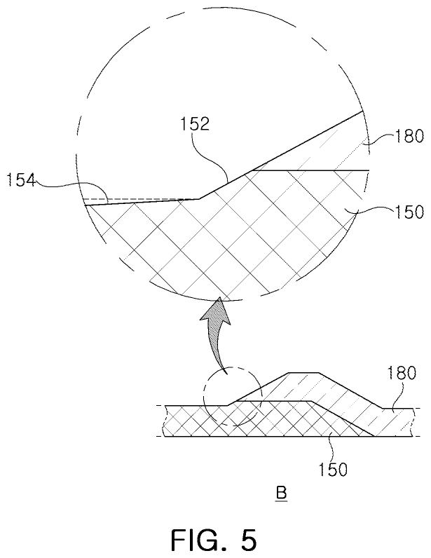

As illustrated in more detail in FIGS. 4 and 5, the lower electrode 150 may be provided with a first inclined surface 152 extending along an inclined surface L of the insertion layer 180 in a region disposed between the insertion layers 180, and a second inclined surface 154 disposed inside the first inclined surface 152. The slope directions of the first inclined surface, the second inclined surface, and the inclined surface of the insertion layer may be the same. For example, an inclination angle of the first inclined surface 152 and an inclination angle of the second inclined surface 154 may differ. The inclination angle of the first inclined surface 152 may be greater than the inclination angle of the second inclined surface 154. In addition, a thickness of the lower electrode 150 in a region disposed inside a second inclined surface 154 may be thinner than the thickness of the lower electrode 150 in a region in which the first and second inclined surfaces 152 and 154 are disposed. As an example, a thickness difference of the lower electrode 150 in an active region may be 30 Å or less. In other words, when the thickness of the lower electrode 150 is measured at the same position of each lower electrode 150 provided in the bulk-acoustic wave resonator 100 disposed adjacent during manufacturing, a difference between a maximum thickness of the lower electrode 150 and a maximum thickness of the lower electrode 150 may be 30 Å or less.

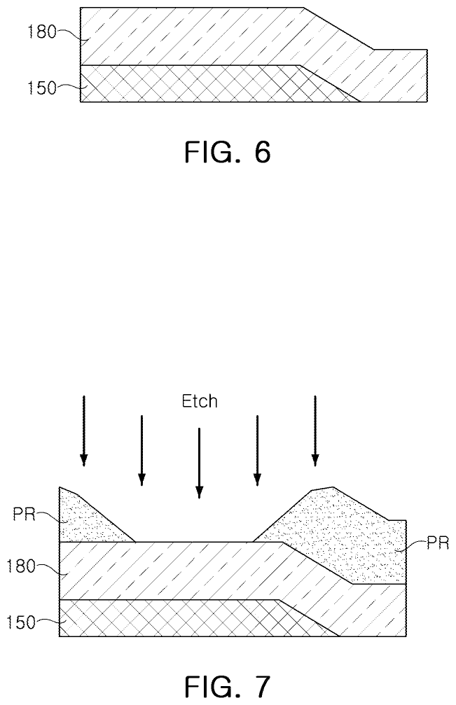

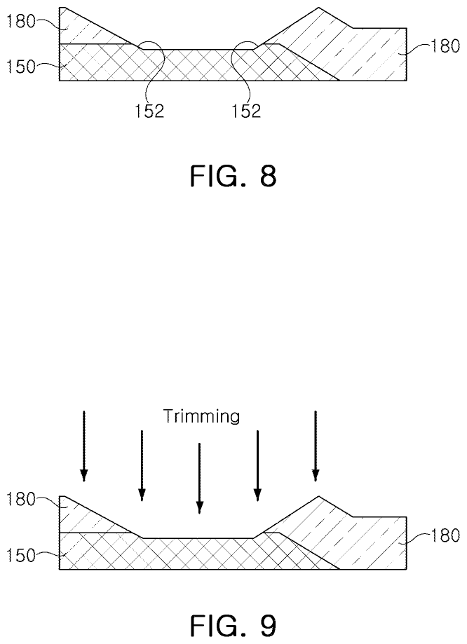

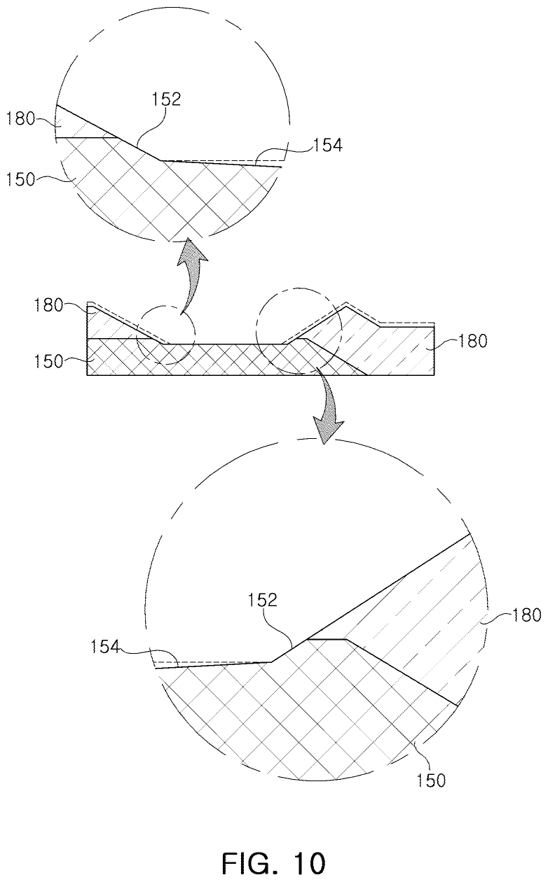

In more detail, as illustrated in FIG. 6, the insertion layer 180 may be stacked to entirely cover the lower electrode 150 such that the insertion layer 180 is formed after deposition of the lower electrode 150. Thereafter, as illustrated in FIG. 7, a photoresist PR may be stacked to cover a portion of the insertion layer 180. Thereafter, as illustrated in FIG. 7, the insertion layer 180 may be removed by an etching process. In this case, as illustrated in FIG. 8, the insertion layer 180 covered with the photoresist PR (see FIG. 7) may remain, and the insertion layer 180 not covered with the photoresist PR may be removed. In addition, a portion of the lower electrode 150 may also be removed by an etching process. Accordingly, the first inclined surface 152 may be formed. Thereafter, as illustrated in FIG. 9, a planarization (trimming) process of the lower electrode 150 may be performed. Accordingly, a second inclined surface 154 may be formed on the lower electrode 150. In this case, as illustrated in FIG. 10, a thickness of the insertion layer 180 may be reduced as the insertion layer 180 is also lost together with the lower electrode 150. When the thickness of the lower electrode 150 is measured at the same position of each lower electrode 150 provided in the bulk-acoustic wave resonator 100 disposed adjacent during manufacturing through the above-described manufacturing process, a difference between a maximum thickness of the lower electrode 150 and a minimum thickness of the lower electrode 150 may be 30 Å or less.

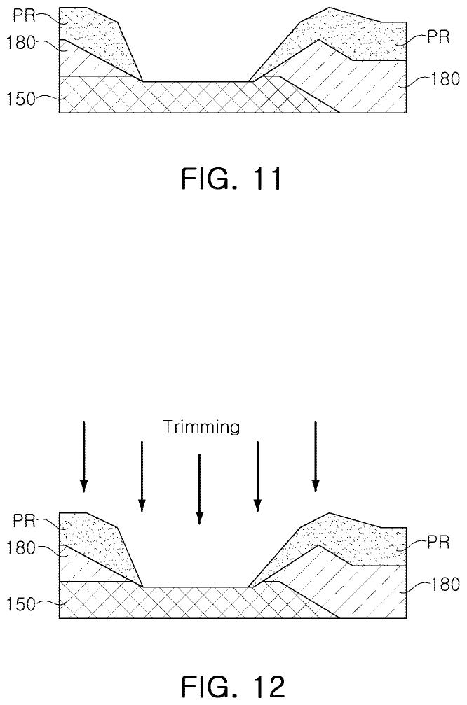

The first and second inclined surfaces 152 and 154 may also be formed by a manufacturing method below. For example, as described above, as illustrated in FIGS. 5 to 7, the first inclined surface 152 may be formed. Thereafter, as illustrated in FIG. 11, for the planarization process of the lower electrode 150, the photoresist PR may be stacked again to cover an edge of the lower electrode 150 and the insertion layer 180. Thereafter, as illustrated in FIG. 12, the planarization (trimming) process of the lower electrode 150 may be performed.

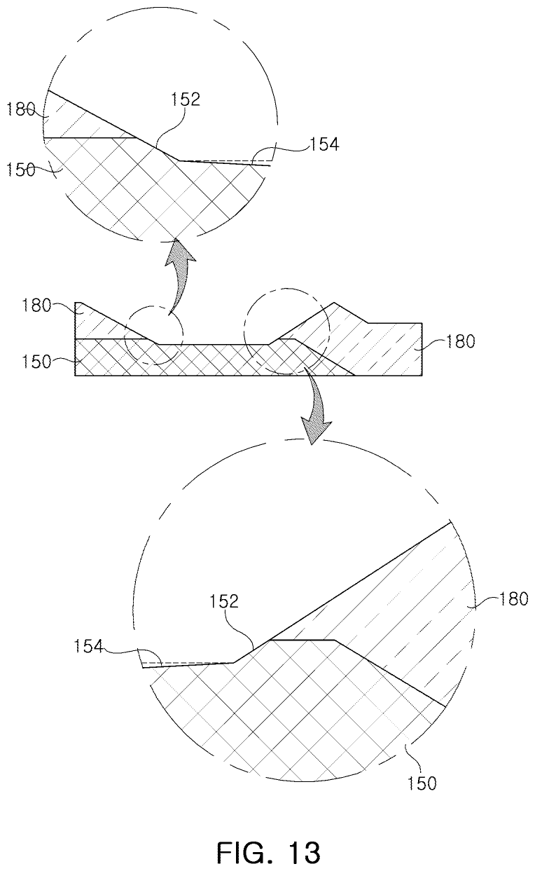

Accordingly, the second inclined surface 154 may be formed on the lower electrode 150. Then, as illustrated in FIG. 13, the photoresist PR may be removed.

As described above, the planarization process of the lower electrode 150 may be performed, such that the lower electrode 150 may be formed to have a thickness difference, that is, a thickness difference between a thickest portion and a thinnest portion of the lower electrode 150 in the active region, of 30 Å or less.

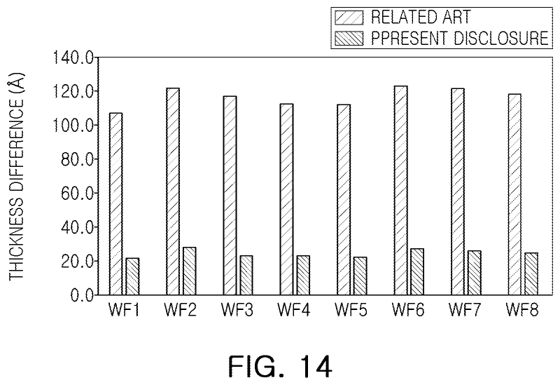

As indicated in the graph of FIG. 14, when the planarization process of the lower electrode 150 is performed, it can be seen that the thickness difference between the thickest portion and the thinnest portion of the lower electrode 150 disposed in the active region is significantly different as compared to that according to the related art in which the planarization process of the lower electrode 150 is not performed. That is, according to the related art, it can be seen that the thickness difference of the lower electrode 150 disposed in the active region is approximately 105 Å to 125 Å. However, according to the present disclosure, it can be seen that the thickness difference between the thickest portion and the thinnest portion of the lower electrode 150 disposed in the active region is approximately 22 Å to 27 Å.

The piezoelectric layer 160 may be formed to cover at least the lower electrode 150 disposed on the upper portion of the cavity C. The piezoelectric layer 160, a portion producing a piezoelectric effect of converting electrical energy into mechanical energy in the form of acoustic waves, may be formed of one of aluminum nitride (AlN), zinc oxide (ZnO), and lead zirconium titanium oxide (PZT; PbZrTiO). When the piezoelectric layer 160 is formed of aluminum nitride (AlN), the piezoelectric layer 160 may further include a rare earth metal. As an example, the rare earth metal may include any one or any combination of any two or more of scandium (Sc), erbium (Er), yttrium (Y), and lanthanum (La). In addition, as an example, a transition metal may include any one or any combination of any two or more of titanium (Ti), zirconium (Zr), hafnium (Hf), tantalum (Ta), and niobium (Nb). In addition, magnesium (Mg), a divalent metal, may also be included.

The piezoelectric layer 160 may include a piezoelectric portion 162 disposed on a flat portion S, and a bent portion 164 disposed on an expanded portion E.

The piezoelectric portion 162 may be a portion directly stacked on an upper surface of the lower electrode 150. Accordingly, the piezoelectric portion 162 may be interposed between the lower electrode 150 and the upper electrode 170 to have a flat shape together with the lower electrode 150 and the upper electrode 170.

The bent portion 164 may be defined as a region extending outwardly from the piezoelectric portion 162 and positioned in the expanded portion E.

The bent portion 164 may be disposed on the insertion layer 180 to be described below, and may be formed to have a raised shape along the shape of the insertion layer 180. Accordingly, the piezoelectric layer 160 may be bent at a boundary between the piezoelectric portion 162 and the bent portion 164, and the bent portion 164 may be raised to correspond to the thickness and shape of the insertion layer 180.

The bent portion 164 may be divided into an inclined portion 164a and an extended portion 164b.

The inclined portion 164a refers to a portion formed to be inclined along the inclined surface L of the insertion layer 180, to be described below. The extended portion 164b refers to a portion extending outwardly from the inclined portion 164a.

The inclined portion 164a may be formed parallel to the inclined surface L of the insertion layer 180, and an inclination angle of the inclined portion 164a may be formed to be the same as an inclination angle θ of the inclined surface L of the insertion layer 180.

The upper electrode 170 may be formed to cover at least the piezoelectric layer 160 disposed on the upper portion of the cavity C. The upper electrode 170 may be used as one of an input electrode and an output electrode for inputting and outputting an electrical signal such as a radio frequency (RF) signal or the like. That is, when the lower electrode 150 is used as an input electrode, the upper electrode 170 may be used as an output electrode. When the lower electrode 150 is used as an output electrode, the upper electrode 170 may be used as an input electrode.

The upper electrode 170 may be formed using, as an example, a conductive material such as molybdenum (Mo) or alloys thereof. However, the present disclosure is not limited thereto, and the upper electrode 170 may be formed of a conductive material, such as ruthenium (Ru), tungsten (W), iridium (Ir), platinum (Pt), copper (Cu), titanium (Ti), tantalum (Ta), nickel (Ni), chromium (Cr), or the like, or alloys thereof.

The active region refers to a region in which the lower electrode 150, the piezoelectric layer 160, and the upper electrode 170 all overlap each other.

The insertion layer 180 may be disposed between the lower electrode 150 and the piezoelectric layer 160. The insertion layer 180 may be formed of a dielectric, such as silicon oxide (SiO₂), aluminum nitride (AlN), aluminum oxide (Al₂O₃), silicon nitride (Si₃N₄), manganese oxide (MgO), zirconium oxide (ZrO₂), lead zirconate titanate (PZT), gallium arsenide (GaAs), hafnium oxide (HfO₂), aluminum oxide (Al₂O₃), titanium oxide (TiO₂), zinc oxide (ZnO), or the like, but may be formed of a material different from that of the piezoelectric layer 160.

In addition, at least a portion of the insertion layer 180 may be disposed between the piezoelectric layer 160 and the lower electrode 150. As an example, the insertion layer 180 may have a ring shape.

The passivation layer 190 may be formed in a region excluding a portion of the lower electrode 150 and the upper electrode 170. The passivation layer 190 may serve to prevent the upper electrode 170 and the lower electrode 150 from being damaged during the process.

The passivation layer 190 may use, as an example, a dielectric layer containing one of silicon nitride (Si₃N₄), silicon oxide (SiO₂), manganese oxide (MgO), zirconium oxide (ZrO₂), aluminum nitride (AlN), lead zirconate titanate (PZT), gallium arsenide (GaAs), hafnium oxide (HfO₂), aluminum oxide (Al₂O₃), titanium oxide (TiO₂), and zinc oxide (ZnO).

The metal pad 195 may be formed on a portion of the lower electrode 150 and the upper electrode 170 in which the passivation layer 190 is not formed. As an example, the metal pad 195 may be formed of a material such as gold (Au), a gold-tin (Au—Sn) alloy, copper (Cu), a copper-tin (Cu—Sn) alloy, aluminum (Al), an aluminum alloy, or the like. For example, the aluminum alloy may be an aluminum-germanium (Al—Ge) alloy.

As described above, the thickness difference of the lower electrode 150 in the active region may be reduced by performing an additional planarization process on the lower electrode 150, thereby improving a frequency variation.

The present disclosure provides a bulk-acoustic wave resonator capable of improving a frequency variation, in addition to improving the trimming effect of a lower electrode.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A bulk-acoustic wave resonator comprising:
a substrate;
a lower electrode, disposed on the substrate, comprising a first inclined surface and a second inclined surface; and
an insertion layer disposed on an edge of the lower electrode,
wherein the first inclined surface extends from an inclined surface of the insertion layer in a region disposed inside the insertion layer, and
the second inclined surface extends from the first inclined surface in a region inside a region of the first inclined surface.

2. The bulk-acoustic wave resonator of claim 1, wherein an inclination angle of the first inclined surface and an inclination angle of the second inclined surface are different from each other.

3. The bulk-acoustic wave resonator of claim 2, wherein the inclination angle of the first inclined surface is greater than the inclination angle of the second inclined surface.

4. The bulk-acoustic wave resonator of claim 1, wherein a thickness of the lower electrode in a region disposed inside the second inclined surface is thinner than the thickness of the lower electrode disposed in a region in which the first and second inclined surfaces are disposed.

5. The bulk-acoustic wave resonator of claim 4, wherein a thickness difference at a same position of the lower electrode and another lower electrode of another bulk-acoustic wave resonator adjacently disposed is 30 Å or less.

6. The bulk-acoustic wave resonator of claim 1, wherein the lower electrode is formed of gold (Au), molybdenum (Mo), iridium (Ir), aluminum (Al), platinum (Pt), titanium (Ti), tungsten (W), palladium (Pd), tantalum (Ta), chromium (Cr), nickel (Ni), or a metal alloy, including at least one of gold (Au), molybdenum (Mo), iridium (Ir), aluminum (Al), platinum (Pt), titanium (Ti), tungsten (W), palladium (Pd), tantalum (Ta), chromium (Cr), and nickel (Ni).

7. The bulk-acoustic wave resonator of claim 1, further comprising:
a piezoelectric layer disposed to cover the insertion layer and the lower electrode; and
an upper electrode disposed to cover at least a portion of the piezoelectric layer.

8. The bulk-acoustic wave resonator of claim 7, further comprising:
a membrane layer disposed between the substrate and the lower electrode, the membrane layer having a cavity disposed therebelow;
an etch stop layer disposed outside the cavity; and
a sacrificial layer disposed outside the etch stop layer.

9. The bulk-acoustic wave resonator of claim 8, further comprising:
a passivation layer disposed on an upper portion of the upper electrode; and
a metal pad connected to the lower electrode and the upper electrode.

10. A bulk-acoustic wave resonator comprising:
a substrate;
a lower electrode disposed on the substrate;
an insertion layer disposed on an edge of the lower electrode;
a piezoelectric layer disposed to cover the insertion layer and the lower electrode; and
an upper electrode disposed to cover at least a portion of the piezoelectric layer,
wherein a portion of the lower electrode, disposed in an active region in which the lower electrode, the piezoelectric layer, and the upper electrode all overlap each other, comprises a first inclined surface extending from an inclined surface of the insertion layer, and a second inclined surface extending from the first inclined surface.

11. The bulk-acoustic wave resonator of claim 10, wherein an inclination angle of the first inclined surface and an inclination angle of the second inclined surface are different from each other.

12. The bulk-acoustic wave resonator of claim 11, wherein the inclination angle of the first inclined surface is greater than the inclination angle of the second inclined surface.

13. The bulk-acoustic wave resonator of claim 10, wherein a thickness of the lower electrode in a region disposed inside the second inclined surface is thinner than the thickness of the lower electrode disposed in a region in which the first and second inclined surfaces are disposed.

14. The bulk-acoustic wave resonator of claim 13, wherein a difference between a maximum thickness and a minimum thickness of the portion of the lower electrode in the active region is 30 Å or less.
